(19) United States
(12) Patent Application Publication
(10) Pub. No.: US 2026/0152850 A1
(43) Pub. Date: Jun. 4, 2026

(54) PRECURSORS COMPRISING AN ENAMINOLATE LIGAND

(71) Applicant: ASM IP Holding B.V., Almere (NL)

(72) Inventors: Charles Dezelah, Helsinki (FI); Patricio Eduardo Romero, Boutersem (BE)

(21) Appl. No.: 19/401,801

(22) Filed: Nov. 26, 2025

Related U.S. Application Data
(60) Provisional application No. 63/726,357, filed on Nov. 29, 2024.

(51) Int. Cl. C23C 16/455; C23C 16/52

(52) U.S. Cl. CPC C23C 16/45553; C23C 16/52; H10P 14/43; H10P 14/6339

(57) ABSTRACT

The present invention relates to compositions, precursor vessels, methods and systems for depositing metals from group 4, group 5, group 6 or group 13, as well as methods for synthesizing metal precursors. Compositions of the present invention comprise a coordination compound comprising a metal from group 5, group 6 or group 13, and at least one enaminolate ligand.

### CROSS-REFERENCE TO RELATED APPLICATION(S)

This application claims the benefit of U.S. Provisional Application 63/726,357 filed on Nov. 29, 2024, the entire contents of which are incorporated herein by reference.

### TECHNICAL FIELD OF THE INVENTION

The present invention relates to the field of deposition of films comprising a metal from groups 4, 5, 6 or 13. In particular, the present invention relates to precursors for said deposition.

### BACKGROUND OF THE INVENTION

Deposition techniques such as chemical vapor deposition (CVD), and, more in particular, atomic layer deposition (ALD), are essential in the fabrication of semiconductor devices, enabling the controlled formation of thin films at the atomic level. These processes are critical for producing materials with precise compositions and properties required for advanced electronic applications.

Metals from groups 4, 5, 6, and 13 of the periodic table are often used in the deposition of metal, metal oxide, and metal nitride films. These metals, when provided as pure metals or nitrides of these metals, are valued for their thermal, chemical, and mechanical stability, as well as their excellent electrical conductivity. Such properties make them suitable for back-end-of-line (BEOL) applications in semiconductor device manufacturing. At the same time, oxides of these metals are typically dielectrics with good thermal, chemical, and mechanical stability, several of which may be useful for high-k applications in transistor devices, e.g., MOSFET.

However, depositing these metals presents several challenges. One significant challenge is achieving high-purity films. Impurities in the deposited films can adversely affect the electrical and physical properties, leading to compromised device performance. Controlling impurity levels is critical, yet difficult, due to the potential introduction of contaminants from precursors or the deposition environment.

Another challenge is the preference for low-temperature deposition processes. High deposition temperatures can be detrimental to underlying layers and materials in multilayer device architectures, especially in BEOL processes where temperature-sensitive components may be present. Consequently, there is a need for deposition methods that can operate effectively at lower temperatures without sacrificing film quality.

Additionally, the oxidation state of the metal during deposition plays a crucial role. Depositing metals in lower oxidation states can be advantageous, as it may facilitate subsequent processing steps to achieve the desired metallic state or specific material phases with optimal properties. However, stabilizing metal precursors in low oxidation states suitable for vapor-phase deposition is often challenging. These species can be less stable or have inadequate volatility, making them less practical for use in CVD or ALD processes.

In view of the above problems, selecting appropriate chemical precursors for the deposition of these metals is a complex task. Precursors must exhibit suitable physical and chemical properties, such as volatility, thermal stability, and reactivity, to enable precise control over the deposition process. Finding compounds that meet these criteria while also addressing issues related to purity, deposition temperature, and oxidation state remains a significant challenge in the field.

Therefore, there is still a need for further advancements in the field to address at least some of these challenges.

### SUMMARY OF THE INVENTION

It is an objective of the present invention to provide compositions that address at least some of the above problems.

The above objective is accomplished by a composition, a precursor vessel comprising the composition, and a deposition method and an apparatus using the composition, according to the present invention.

It is an advantage of embodiments of the present invention that precursors are provided that are suitable for advanced deposition techniques such as chemical vapor deposition and atomic layer deposition, which are useful for the controlled deposition of thin films at the atomic level.

It is an advantage of embodiments of the present invention that the enaminolate ligands of the precursors are versatile and can attach to a variety of metal atoms in a range of oxidation states, enhancing the stability and precursor properties of low oxidation state metal complexes.

It is an advantage of embodiments of the present invention that low oxidation state metal precursors for metals from groups 4, 5, 6, and 13 can be stabilized using enaminolate ligands.

It is an advantage of embodiments of the present invention that good deposition of metal, metal oxide, and metal nitride films comprising metals from groups 4, 5, 6, and 13, which are important for back-end-of-line applications due to their good thermal, chemical, and mechanical stability, as well as excellent electrical conductivity, may be achieved.

In an aspect, the present invention relates to a composition comprising a precursor comprising a coordination compound comprising:
a metal from group 4, group 5, group 6 or group 13, and
at least one enaminolate ligand.

In another aspect, the present invention relates to a precursor vessel comprising a composition comprising a precursor comprising a coordination compound comprising:
a metal from group 4, group 5, group 6 or group 13, and
at least one enaminolate ligand,
wherein the vessel is configured to supply a vapor of the coordination compound to a reaction chamber of a vapor deposition system, preferably to a reaction chamber of a semiconductor processing apparatus.

In a further aspect, the present invention relates to a method for depositing a material comprising a metal from group 4, group 5, group 6 or group 13 on a substrate, the method comprising:
providing a substrate in a reaction chamber, and then providing, into the reaction chamber, a vapor-phase composition comprising a precursor comprising a coordination compound comprising:
the metal, and
at least one enaminolate ligand,
thereby forming a layer comprising the metal on a portion of a surface of the substrate.

In yet a further aspect, a method of synthesizing a precursor for vapor deposition is disclosed. In embodiments, the method comprises reacting a potassium salt of an enamine of formula

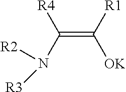

with a halide of a group 4, group 5, group 6 or group 13 metal.

In further embodiments of the method of synthesizing a precursor for vapor deposition, the method comprises reacting a free ligand of formula

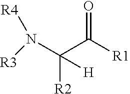

with a basic metal compound of a group 4, group 5, group 6 or group 13 metal.

In some embodiments, the basic metal compound of a group 4, group 5, group 6 or group 13 metal is selected from homoleptic metal alkyls, homoleptic dialkylamido compounds and homoleptic alkoxide compounds.

In yet a further aspect, the present invention relates to a system for depositing a material comprising a metal from group 4, group 5, group 6 or group 13 on a substrate, the system comprising:
a reaction chamber for receiving the substrate,
a first source for providing a vapor-phase composition comprising a precursor comprising a coordination compound, wherein the first source is in gas communication via a first valve with the reaction chamber, the coordination compound comprising:
the metal, and
at least one enaminolate ligand,
a controller operably connected to the first valve, wherein the controller is configured and programmed to open the first valve to provide a flow of the composition into the reaction chamber and to close the first valve to cease the flow of the composition into the reaction chamber.

Particular and preferred aspects of the invention are set out in the accompanying independent and dependent claims. Features from the dependent claims may be combined with features of the independent claims and with features of other dependent claims as appropriate and not merely as explicitly set out in the claims.

Although there has been constant improvement, change and evolution of devices in this field, the present concepts are believed to represent substantial new and novel improvements, including departures from prior practices, resulting in the provision of more efficient, stable and reliable devices of this nature.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a schematic representation of a deposition system in accordance with embodiments of the present invention.

FIG. 2 is a schematic representation of a film formed on a substrate in the reaction chamber of the deposition system of FIG. 1.

In the different figures, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising” should not be interpreted as being restricted to the means listed thereafter; it does not exclude other elements or steps. It is thus to be interpreted as specifying the presence of the stated features, integers, steps or components as referred to but does not preclude the presence or addition of one or more other features, integers, steps or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

In the current disclosure, the term “alkyl group” comprises all linear, branched and cyclic isomers of an alkyl. For example, the term “C1 to C6 alkyl” can mean any of methyl, ethyl, n-propyl, isopropyl, n-butyl, isobutyl, sec-butyl, tert-butyl, n-pentyl, isopentyl, neopentyl, n-hexyl, isohexyl, neohexyl, 2-methylpentyl, 3-methylpentyl, 2,2-dimethylbutyl, 2,3-dimethylbutyl, cyclopropyl, cyclobutyl, cyclopentyl and cyclohexyl.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

Within the context of the present invention, the terms “precursor” and “co-reactant” may refer to molecules (compounds, or molecules comprising a single element such as O₂ or O₃) that participate in a chemical reaction that produces another compound or an element. A precursor typically contains portions that are at least partly incorporated into the compound or element resulting from the chemical reaction in question. Such a resulting compound or element may be deposited on a substrate. In some instances, a co-reactant is a precursor. In other instances, the compound or element that results from the chemical reaction does not contain a portion of the co-reactant (an element or group within the co-reactant) and therefore the co-reactant is not a precursor. In some embodiments, a precursor or a co-reactant is provided in a mixture of two or more compounds. In a mixture, the other compounds in addition to the precursor may be inert compounds or elements. In some embodiments, a precursor or a co-reactant is provided in a composition. Composition may be a solution or a gas in standard conditions.

Within the context of the present invention, the term “layer” and/or (thin) “film” can refer to any continuous or non-continuous material, such as material deposited by the methods disclosed herein, and these terms may be used interchangeably. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In embodiments, a layer or thin film may have a thickness of from 0.1 nm to 1 μm, such as from 0.5 nm to 200 nm.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a sheet, a plate, or a workpiece. Substrates in the form of a sheet may extend beyond the bounds of a reaction space or a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, Mo, Mo germanium, Mo oxide, gallium arsenide, gallium nitride, and Mo carbide. A substrate can include one or more layers overlying a bulk material, for example the substrate may include nitrides, for example TiN, oxides, insulating materials, dielectric materials, conductive materials, metals, such as tungsten, ruthenium, Group 6 metal, cobalt, aluminum, or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate.

The invention will now be described by a detailed description of several embodiments of the invention. It is clear that other embodiments of the invention can be configured according to the knowledge of persons skilled in the art without departing from the technical teaching of the invention, the invention being limited only by the terms of the appended claims.

In a first aspect, the present invention relates to a composition comprising a precursor comprising a coordination compound comprising:
a metal from group 4, group 5, group 6 or group 13, and
at least one enaminolate ligand.

In preferred embodiments, the composition comprising the precursor comprising the coordination compound comprises:
a metal from group 5, group 6 or group 13, and
at least one enaminolate ligand.

Such preferred embodiments, offer improvement deposition of metal from group 5, group 6 or group 13.

In embodiments, each enaminolate ligand may independently be bonded monodentately or bidentately to the metal. In embodiments, each enaminolate ligand may independently be bonded monodentately to the metal. In embodiments, each enaminolate ligand may be bonded bidentately to the metal. In particular, the enaminolate ligand comprises both an oxygen and nitrogen atom, wherein one or both of them may be bonded to the metal. Typically, each enaminolate ligand carries a single negative charge, that may be localized on the oxygen atom.

In embodiments, the coordination compound contains a single metal atom. In some embodiments, the coordination compound contains more than one metal atom. In some embodiments, the enaminolate ligand is bonded to two metal atoms. In such embodiments, the enaminolate may be bonded monodentately through oxygen to a first metal atom and monodentately through nitrogen to a second metal atom. In embodiments, the first metal atom and the second metal atom may be the same chemical element. In embodiments, the first metal atom and the second metal atom may be different chemical elements.

Enaminolate ligands are known in the art, and have previously been used for atomic layer deposition. However, they were only as precursors for some rare earth elements including Y, La, Er and Lu (Jayakodiarachchi, N., Evans, P. G., Ward, C. L., & Winter, C. H. (2021). Evaluation of volatility and thermal stability in monomeric and dimeric lanthanide (III) complexes containing enaminolate ligands. Organometallics, 40(9), 1270-1283). Within the context of these rare earth elements, oxidation and reduction were of no concern.

The inventors of the present invention have realized that these enaminolate ligands may attach to a variety of metal atoms, in a variety of oxidation states. Indeed, as a typically bidentate, monoanionic ligand with good tunability of alkyl substituents, enaminolate ligands are expected to be good at stabilizing monomeric coordination compounds comprising the metal in a low oxidation state. Furthermore, as their structure may be tuned to optimize their properties for precursors, the enaminolate ligand may be used to provide a coordination compound having good precursor properties. The enaminolate ligand, therefore, allows for the deposition of the metal at any oxidation state that is required for a particular purpose, including in a low oxidation state, which is typically difficult when using ligands of the state of the art.

It is an advantage of embodiments of the present invention that the enaminolate ligand may be thermally stable. Their high thermal stability may result in a good and predictable deposition and prevent contamination of deposited material with decomposition products of the ligand.

In some embodiments, the metal is in an oxidation state below the highest common oxidation state for the metal. The highest common oxidation state is typically +5 for group 5 metals. The highest common oxidation state is typically +6 for group 6 metals. The highest common oxidation state is typically +4 for group 4 metals. The highest common oxidation state is typically +3 for group 13 metals. In embodiments, the metal may be Ti²⁺, Ti³⁺, Zr³⁺, Hf²⁺, Hf³⁺, Cr²⁺, Cr³⁺, Mo³⁺, W³⁺, V²⁺, V³⁺, Ta³⁺, Nb³⁺, Ga¹⁺, In¹⁺, Mo²⁺, Mo⁴⁺, W²⁺, W⁴⁺, V⁴⁺, Ta²⁺, Ta⁴⁺, Nb²⁺, or Nb⁴⁺. In some preferred embodiments, the metal may be Cr²⁺, Cr³⁺, Mo³⁺, W³⁺, V²⁺, V³⁺, Ta³⁺, Nb³⁺, Ga¹⁺, In¹⁺, Mo²⁺, Mo⁴⁺, W²⁺, W⁴⁺, V⁴⁺, Ta²⁺, Ta⁴⁺, Nb²⁺, or Nb⁴⁺. It is an advantage of these embodiments that low oxidation state precursors exhibit higher reactivity and provide easier pathways to reduction to the zero-oxidation state during deposition processes.

However, this is not required. In some embodiments, the metal is in the highest common oxidation state for the metal. In some embodiments, the metal may be Ti⁴⁺, Zr⁴⁺, Hf⁴⁺, V⁺⁵, Nb⁺⁵, W⁶⁺, Mo⁺⁶, Al³⁺, In³⁺, or Ga³⁺. In some preferred embodiments, the metal may be V⁺⁵, Nb⁺⁵, W⁶⁺, Mo⁺⁶, Al³⁺, In³⁺, or Ga³⁺.

In some embodiments, the metal is from group 5 or group 6. In some embodiments, the metal is selected from a group consisting of vanadium (V), niobium (Nb), and tantalum (Ta). In some of these embodiments, the metal is selected from a group consisting of chromium (Cr), molybdenum (Mo), and tungsten (W).

In some embodiments, the metal is from group 4. In some embodiments, the metal is selected from a group consisting of titanium (Ti), zirconium (Zr), and hafnium (Hf). In other embodiments, the metal is not a group 4 metal.

In some embodiments, the metal is from group 13. In embodiments, the metal is aluminum (Al). In some embodiments, the metal is gallium (Ga). In embodiments, the metal is indium (In).

In embodiments, each enaminolate ligand has the following chemical formula I:

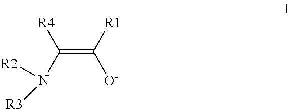

In embodiments, R1 may be hydrogen or a C1 to C8 alkyl group or an alkylsilyl group. In embodiments, R1 may be hydrogen or a C1 to C8 alkyl group. In some embodiments, R1 is a C3 or C4 alkyl group. In some embodiments, R1 is a butyl group. In some embodiments, R1 is a tert-butyl group. In embodiments, R1 may be the alkylsilyl group, containing a silicon atom bonded to three alkyl groups, wherein each of the three alkyl groups is independently selected from C1 to C8 alkyl groups, preferably from C1 to C4 alkyl groups, more preferably from C1 to C2 alkyl groups. In some embodiments, R1 is SiMe₃ or SiEt₃. In embodiments wherein R1 is the alkylsilyl group, the silicon atom may be directly bonded to the carbon atom to which R1 is bonded. In embodiments wherein R1 is the alkylsilyl group, the silicon atom may be bonded to the carbon atom to which R1 is bonded via a C1 to C4 chain, preferably a C1 to C2 chain, more preferably a C1 chain.

In embodiments, R2 and R3 may each be independently selected from C1 to C8 alkyl groups or alkylsilyl groups. In some embodiments, R2 and R3 may each be independently selected from C1 to C8 alkyl groups. In some embodiments, R2 and R3 are the same alkyl group. For example, in some embodiments, R2 and R3 are methyl. In some embodiments, R2 and R3 are ethyl. In some embodiments, R2, R3 and the N to which they are bonded may together form a four to nine membered ring. In some embodiments, R2 may be the alkylsilyl group, containing a silicon atom bonded to three alkyl groups, wherein each of the three alkyl groups is independently selected from C1 to C8 alkyl groups, preferably from C1 to C4 alkyl groups, more preferably from C1 to C2 alkyl groups. In some embodiments, R2 may be SiMe₃ or SiEt₃. In embodiments wherein R2 is the alkylsilyl group, the silicon atom may be directly bonded to the nitrogen atom to which R2 is bonded. In embodiments wherein R2 is the alkylsilyl group, the silicon atom may be bonded to the nitrogen atom to which R2 is bonded via a C1 to C4 chain, preferably a C1 to C2 chain, more preferably a C1 chain. In some embodiments, R3 may be the alkylsilyl group, containing a silicon atom bonded to three alkyl groups, wherein each of the three alkyl groups is independently selected from C1 to C8 alkyl groups, preferably from C1 to C4 alkyl groups, more preferably from C1 to C2 alkyl groups. In some embodiments, R3 may be SiMe₃ or SiEt₃. In some embodiments wherein R3 is the alkylsilyl group, the silicon atom may be directly bonded to the nitrogen atom to which R3 is bonded. In embodiments wherein R3 is the alkylsilyl group, the silicon atom may be bonded to the nitrogen atom to which R3 is bonded via a C1 to C4 chain, preferably a C1 to C2 chain, more preferably a C1 chain.

In embodiments, R4 may be hydrogen or a C1 to C8 alkyl group or an alkylsilyl group. In embodiments, R4 may be hydrogen or a C1 to C8 alkyl group. In some embodiments, R2, R4, the carbon atom to which R4 is bonded and the N to which R2 is bonded may together form a four to nine membered ring. In some embodiments, R1, R4, the carbon atom to which R1 is bonded, and the carbon atom to which R4 is bonded, together form a four to nine membered ring. Each of the mentioned rings may independently be substituted. Each of the mentioned rings preferably consists, apart from possibly the nitrogen atom to which R2 and R3 are attached, of carbon atoms. In some embodiments, R4 may be the alkylsilyl group, containing a silicon atom bonded to three alkyl groups, wherein each of the three alkyl groups is independently selected from C1 to C8 alkyl groups, preferably from C1 to C4 alkyl groups, more preferably from C1 to C2 alkyl groups. In some embodiments, R4 may be SiMe₃ or SiEt₃. In embodiments wherein R4 is the alkylsilyl group, the silicon atom may be directly bonded to the carbon atom to which R4 is bonded. In embodiments wherein R4 is the alkylsilyl group, the silicon atom may be bonded to the carbon atom to which R4 is bonded via a C1 to C4 chain, preferably a C1 to C2 chain, more preferably a C1 chain.

In some embodiments, R4 may be hydrogen or a C1 to C6 alkyl group, preferably hydrogen or a C1 to C4 alkyl group. In preferred embodiments, R4 is hydrogen.

Preferably, the conjugate acid of the enaminolate has a high pKa, in which case the enaminolate may have a high affinity for the metal, which may result in a stable coordination compound. At the same time, the high pKa may result in facile protonation of the enaminolate, so that the enaminolate may have a high reactivity towards protic co-reactants such as H₂O. In particular, by said protonation, the enaminolate may be transformed into an (uncharged) α-aminoketone. The α-aminoketone may easily release from the metal. This may facilitate vapor deposition of the coordination compound of embodiments of the present invention on a substrate, with subsequent release of the enaminolate from the substrate.
In some embodiments, R4 is hydrogen. In these embodiments, each enaminolate ligand has the following chemical formula (II):

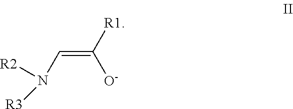

Each of R1, R2, and R3 may be independently selected as correspondingly described above. In some embodiments, R1 is hydrogen or a C1 to C8 alkyl group. In some embodiments, R2 and R3 may each independently be selected from C1 to C8 alkyl groups. In some embodiments, R1 is a C3 or C4 alkyl group. In some embodiments, R1 is a butyl group. In some embodiments, R1 is a tert-butyl group. In some embodiments, R2 and R3 are the same alkyl group. For example, in some embodiments, R2 and R3 are methyl. In some embodiments, R2 and R3 are ethyl. In some embodiments, R2 and R3 may, together with the nitrogen atom to which they are attached, form an optionally substituted, ring with from 4 to 9 atoms, preferably from 4 to 7 atoms. The ring preferably consists, apart from the nitrogen atom to which R2 and R3 are attached, of carbon atoms. In embodiments wherein the ring is substituted, the substitution may be with a C1 to C8 alkyl group, preferably with a C1 to C6 alkyl group. In a particular embodiment, the coordination compound according to the current disclosure comprises at least one enaminolate ligand, in which R1 is tert-butyl, R2 and R3 are methyl, and R4 is H. In some embodiments, R1 is hydrogen or a C1 to C6 alkyl group, and R2 and R3 are each independently selected from C1 to C6 alkyl groups. In some embodiments, R1 is selected from a group consisting of hydrogen, methyl, ethyl, n-propyl, isopropyl, n-butyl, sec-butyl, and tert-butyl, and R2 and R3 are each independently selected from a group consisting of methyl, ethyl, and isopropyl.

In embodiments wherein the coordination compound comprises more than one enaminolate ligand, each enaminolate ligand of the coordination compound may have the same structure. In embodiments wherein the coordination compound comprises more than one enaminolate ligand, different enaminolate ligands of the coordination compound may have different structures.

In some embodiments, the coordination compound is homoleptic.

In some embodiments, the coordination compound has the chemical formula ML₃, wherein M is selected from a group consisting of Ti, Zr, Hf, V, Nb, Ta, Cr, Mo, W, Al, Ga, and In, and wherein each L is an enaminolate ligand. Each L may be the same enaminolate ligand, in which case the coordination compound is homoleptic, but the invention is not limited thereto. In some of these embodiments, the coordination compound is AlL₃, GaL₃, or InL₃, where L is an enaminolate ligand according to the current disclosure. In some embodiments, the coordination compound is heteroleptic.

In some embodiments, the coordination compound further comprises at least one ligand selected from a group consisting of: a cyclopentadienyl ligand, an amidate ligand, an alkyl ligand, an alkylamido ligand, an imido ligand, an alkoxide ligand, a halide ligand, a guanidinate ligand, and a beta-diketonate ligand.

In some embodiments, the coordination compound has the chemical formula MO₂L₂, wherein M is Cr, Mo, or W, and wherein each L is an enaminolate ligand.

In some embodiments, the coordination compound has the chemical formula MOL₃, wherein M is V, Nb, or Ta and wherein each L is an enaminolate ligand.

In some embodiments, the coordination compound has the chemical formula M(NR)ₓL_{y}, wherein M is V, Nb, Ta, Cr, Mo, or W, wherein each R is an alkyl group or a trialkylsilyl group, wherein each L is an enaminolate ligand, and wherein each of x and y is an integer equal to or greater than one, and wherein x+y is an integer from two to six. In some of these embodiments, each R is independently selected from C1 to C8 alkyl groups, preferably from C1 to C6 alkyl groups, more preferably from C1 to C4 alkyl groups. In some of these embodiments, each R is independently selected from ethyl, isopropyl, sec-butyl, tert-butyl, and tert-pentyl, preferably isopropyl, sec-butyl, tert-butyl, and tert-pentyl. In some embodiments, the trialkylsilyl group may comprise silicon bonded to three alkyl groups, each independently selected from C1 to C8 alkyl groups, preferably from C1 to C4 alkyl groups, more preferably from C1 to C2 alkyl groups. In some of these embodiments, each R is independently selected from trimethylsilyl and triethylsilyl. In some embodiments, x is from 1 to 5, y is from 1 to 5 and x+y is from 2 to 6.

In some embodiments, the coordination compound has the chemical formula MLₓL′_{y}, wherein M is Ti, Zr, Hf, V, Nb, Ta, Cr, Mo, or W, wherein each L is an enaminolate ligand, and wherein each L′ is a ligand selected from a group consisting of: dimethylamido, diethylamido, ethylmethylamido, methoxy, ethoxy, isopropoxy, tert-butoxy, tert-pentoxy, trimethylsiloxy, or triethylsiloxy, N,N′-diisopropylacetamidinate, N,N′-di-tert-butylacetamidinate, N,N′-diisopropylformamidinate, N,N′-di-tert-butylformamidinate, cyclopentadienyl, methylcyclopentadienyl, ethylcyclopentadienyl, isopropylcyclopentadienyl, tert-butylcyclopentadienyl, trimethylsilylcyclopentadienyl, and pentamethylcyclopentadienyl, and wherein each of x and y is an integer equal to or greater than one, and wherein x+y is an integer from two to six. In embodiments, x is from 1 to 5, y is from 1 to 5 and x+y is from 2 to 6.

In some embodiments, the coordination compound has the chemical formula MLₓL′_{y}, wherein M is Al, Ga or In, wherein each L is an enaminolate ligand, and wherein each L′ is a ligand selected from a group consisting of a cyclopentadienyl ligand, an amidate ligand, an alkyl ligand, an aryl ligand, an alkylamido ligand, an imido ligand, an alkoxide ligand, a halide ligand, a guanidinate ligand, and a beta-diketonate ligand, wherein each of x and y is an integer equal to or greater than one and x+y is 3.

In some embodiments, the coordination compound is AlR′₂L, GaR′₂L, or InR′₂L, where L is an enaminolate ligand according to the current disclosure and where each R′ is independently selected from C1 to C4 alkyls and from aryls. In some embodiments, the coordination compound is AlR′L₂, GaR′L₂, or InR′L₂, wherein each L is an enaminolate ligand according to the current disclosure and R′ is independently selected from C1 to C4 alkyls and from aryls. In some embodiments, the at least one alkyl is selected from methyl, ethyl, n-propyl, isopropyl, n-butyl, sec-butyl, isobutyl and tert-butyl. In some embodiments, at least one R′ is an aryl, such as phenyl. In a particular embodiment, the coordination compound comprises one enaminolate ligand, in which R1 is tert-butyl, R2 and R3 are methyl, and R4 is H; and each R′ is a methyl ligand and the metal atom is selected from a group consisting of Al, Ga and In. In another embodiment, the coordination compound comprises one enaminolate ligand, in which R1 is tert-butyl, R2 and R3 are ethyl, and R4 is H; and each R′ is a methyl ligand and the metal atom is selected from a group consisting of Al, Ga and In.

In some embodiments, the coordination compound is AlL(NRR′)₂, GaL(NRR′)₂, or InL(NRR′)₂, wherein L is an enaminolate ligand according to the current disclosure, and wherein R and R′ are independently selected from H, methyl, ethyl, isopropyl, n-propyl, n-butyl, sec-butyl, isobutyl, tert-butyl, trimethylsilyl, and triethylsilyl. In some embodiments, the coordination compound is AlL₂(NRR′), GaL₂(NRR′), or InL₂(NRR′), wherein each L is an enaminolate ligand according to the current disclosure, and wherein R and R′ are independently selected from H, methyl, ethyl, isopropyl, n-propyl, n-butyl, sec-butyl, isobutyl, tert-butyl, trimethylsilyl, and triethylsilyl.

In some embodiments, the coordination compound is AlL(OR)₂, GaL(OR)₂, or InL(OR)₂, wherein L is an enaminolate ligand according to the current disclosure, and wherein R is selected from H, methyl, ethyl, isopropyl, n-propyl, n-butyl, sec-butyl, isobutyl, tert-butyl, trimethylsilyl, and triethylsilyl. In some embodiments, the coordination compound is AlL₂(OR), GaL₂(OR), or InL₂(OR), wherein each L is an enaminolate ligand according to the current disclosure, and wherein R is selected from H, methyl, ethyl, isopropyl, n-propyl, n-butyl, sec-butyl, isobutyl, tert-butyl, trimethylsilyl, and triethylsilyl.

The compositions disclosed herein are typically stable enough for allowing the storage and use over an extended period of time, for example, over several months. The composition is typically adapted to withstand the deposition conditions to allow vapor transfer into a reaction chamber. Additionally, the vaporization rate of the composition under predetermined conditions remains preferably constant. Some compositions may suffer from more than one substance being vaporized from the composition. If the substances differ in volatility, the composition may be enriched in less volatile substances over time. This can lead to a phenomenon called process drift: one or more of the deposition process parameters gradually changes over time as the chemical composition changes. The consequences of process drift may be detrimental in sensitive applications, and the tuning of the process to compensate for the drift may be expensive, difficult, or even impossible.

In embodiments, a purity of the composition, e.g., the coordination compound, is at least 95 wt-%, preferably at least 99 wt-%, more preferably at least 99.9 wt-%, even more preferably at least 99.99 wt-%, yet more preferably at least 99.999 wt-%, still more preferably at least 99.9999 wt-%. Such high purities are typically strongly preferred for chemical vapor deposition, in particular, for atomic layer deposition. Preferably, the composition contains no more than about 5 wt %, or no more than about 4 wt %, or no more than about 3 wt %, or no more than about 2 wt %, or no more than about 1 wt %, or no more than about 0.5 wt %, or no more than about 0.1 wt %, or no more than about 100 ppm, or no more than about 10 ppm, of halogen containing impurities, such as halogen impurities. Preferably, the composition contains no more than about 1 wt %, or no more than about 0.1 wt %, or no more than about 100 ppm, or no more than about 10 ppm, or no more than about 1 ppm, or no more than about 100 ppb, or no more than about 10 ppb, of metal containing impurities, such as metal impurities. Metal impurities may be metals not contained in the coordination compound of embodiments of the present invention. The metal impurities may, for example, comprise alkali metals (e.g., Li, Na, K) and/or alkaline earth metals (e.g., Mg, Ca).

Any features of any embodiment of the first aspect may be independently as correspondingly described for any embodiment of any of the other aspects of the present invention.

In a second aspect, the present invention relates to a precursor vessel comprising a composition comprising a precursor comprising a coordination compound comprising:
a metal from group 4, group 5, group 6 or group 13, and
at least one enaminolate ligand,
wherein the vessel is configured to supply a vapor of the precursor to a reaction chamber of a vapor deposition system, preferably to a reaction chamber of a semiconductor processing apparatus. The reaction chamber of the vapor deposition system, i.e., the vapor deposition system reaction chamber, may be a chemical vapor deposition system reaction chamber. The chemical vapor deposition system reaction chamber may be an atomic layer deposition system reaction chamber.

The composition comprising the precursor comprising the coordination compound is described in the first aspect of the present disclosure. The precursor vessel may be fabricated of a suitable vessel material, such as stainless steel, aluminum, copper, nickel, silver, their alloys, graphite, boron nitride, ceramic material or a combination or mixture of said materials. The vessel material may be a heat-conducting material. The vessel material may be a coated or clad material.

The precursor vessel comprises a housing defining an interior volume of the precursor vessel. The interior volume is adapted for holding the composition comprising the precursor comprising the coordination compound according to embodiments of the present invention. In some embodiments, the interior volume has a substantially circular cylindrical shape, so that the interior volume has a substantially circular floor. However, the interior volume of the precursor vessel may have any shape that facilitates an even flow of a vapor of the precursor and optional carrier gas through the interior volume. In embodiments, the precursor vessel may have a height to width aspect ratio in the range of about 0.5 to 4, for example 1 to 2 or 1 to 3. The height of the precursor vessel is a dimension at an exterior of the precursor vessel from a lid to a portion of the housing farthest away from the lid. The width of the precursor vessel is a largest dimension across the precursor vessel perpendicular to the height.

In some embodiments, the precursor vessel comprises a lid for isolating the interior volume from the surrounding atmosphere. In some of these embodiments, the lid may comprise an inlet for feeding a, typically inert, carrier gas (e.g., N₂, He or Ar) into the interior volume of the precursor vessel. The inlet for feeding the carrier gas may comprise an inlet valve for introducing said carrier gas when the inlet valve is open, and for blocking said carrier gas from being fed into the precursor vessel when the inlet valve is closed. The lid may comprise an outlet for feeding the precursor, and optionally the carrier gas, to the reaction chamber. The outlet may comprise an outlet valve for providing the vapor of the precursor, and the optional carrier gas, to the reaction chamber when the outlet valve is open, and for blocking said chemical precursor, and the optional carrier gas, from being fed to the reaction chamber when the outlet valve is closed.

The precursor vessel may be provided with gas lines extending from the inlet and outlet, isolation valves on the lines, and fittings on the valves, the fittings being configured to connect to gas flow lines of other components of a chemical vapor deposition system. Isolation valves may fluidically isolate the contents of the precursor vessel from the vessel exterior. One isolation valve may be provided upstream of the precursor vessel inlet, and another isolation valve may be provided downstream of the precursor vessel outlet.

The precursor vessel, or a deposition system of which the precursor vessel may be part, may comprise a heater, such as radiant heat lamps or resistive heaters. In some embodiments, the heater may be adapted to heat the precursor vessel to a temperature of from 40° C. to 200° C., for example, to 70° C., 85° C., 90° C., 110° C., 120° C., 140° C., 160° C. or 180° C. In particular during use of the precursor vessel in a vapor deposition method, the heater may be configured to heat up the precursor vessel to a temperature above a volatilization temperature, under a pressure within the precursor vessel, of the precursor.

In some embodiments, the pressure within the precursor vessel may be from 10 to 1000 Pa, although the invention is not limited thereto. In particular, during use in a chemical vapor deposition method, precursor vessels are typically at such a low pressure. The precursor vessel may comprise, or may be coupled to, a pressure control system, for monitoring a pressure in the precursor vessel. The precursor vessel may comprise a valve for coupling the precursor vessel to a vacuum pump.

In some embodiments, the precursor vessel may comprise precursor distribution means for enabling efficient precursor vaporization, e.g., precursor holding structures or carrier gas guiding arrangements in the interior volume of the precursor vessel. The precursor vessel may comprise features for filtering solid particles, to prevent such particles from being present in the vapor phase flow, such as filters or other entrapment structures. Additionally, the inlet and the outlet of the precursor vessel, as well as gas lines extending therefrom, may comprise heaters for heating the valves and gas lines between the precursor vessel and the reaction chamber to prevent the reactant vapor from condensing and depositing on any components.

Any features of any embodiment of the second aspect may be independently as correspondingly described for any embodiment of any of the other aspects of the present invention.

In a third aspect, the present invention relates to a method for depositing a material comprising a metal from group 4, group 5, group 6 or group 13 on a substrate, the method comprising:
providing a substrate in a reaction chamber, and then
providing, into the reaction chamber, a vapor-phase composition comprising a precursor comprising a coordination compound comprising:
the metal, and
at least one enaminolate ligand,
thereby forming a layer, or thin film, comprising the metal on a portion of a surface of the substrate.

The composition comprising the precursor comprising the coordination compound is described in the first aspect of the present disclosure.

In embodiments, the deposition method may be any type of vapor deposition process, including physical vapor deposition processes and chemical vapor deposition processes, such as atomic layer deposition processes.

In some embodiments, the chemical vapor deposition process may be characterized by vapor deposition which is not self-limiting. In embodiments, the chemical vapor deposition process may involve gas phase reactions between the precursor in accordance with the present invention, and another precursor or co-reactant. The precursor in accordance with the present invention, and another precursor or co-reactant may be provided simultaneously to the reaction chamber or substrate, or in partially or completely separated pulses. In some embodiments, precursor in accordance with the present invention, or another precursor or co-reactant, or simultaneously the precursor in accordance with the present invention, and another precursor or co-reactant, are provided until a layer having a desired thickness is deposited.

In some embodiments, a cyclic chemical vapor deposition processes can be used with multiple cycles to deposit a thin film having a desired thickness. In cyclic chemical vapor deposition processes such as atomic layer deposition, the precursors and/or any co-reactants may be provided to the reaction chamber in pulses that do not overlap, or that partially or completely overlap.

In preferred embodiments, the present invention relates to cyclical deposition processes, such as atomic layer deposition. In cyclic deposition processes, during each cycle, the precursor is introduced into the reaction chamber and the coordination compound may be deposited on or chemisorbed to the substrate surface (wherein the substrate surface may be the bare substrate, or may include a previously deposited material from a previous deposition cycle, or another material). In some embodiments, the coordination compound on the substrate surface does not readily react with the coordination compound itself, so that the deposition of the coordination compound may be partially or fully self-limiting. Thereafter, a co-reactant may be introduced into the reaction chamber for converting the chemisorbed precursor to the desired material on the surface. The co-reactant may be capable of further reaction with the precursor. Purging steps may be utilized to remove any excess precursor from the process chamber and/or remove any excess co-reactant and/or reaction byproducts from the reaction chamber. Thus, in some embodiments, the cyclic deposition process comprises purging the reaction chamber after providing the coordination compound into the reaction chamber.

In some embodiments, the method further comprises—after forming said layer—cyclically performing:
optionally purging the reaction chamber, then
providing, into the reaction chamber, a vapor-phase co-reactant, then
optionally purging the reaction chamber, and then
providing, into the reaction chamber, said precursor.

In some embodiments, the method further comprises executing at least one cycle of a cyclic deposition process, each cycle comprising:
providing, into the reaction chamber, a vapor-phase composition comprising the
precursor comprising the coordination compound;
optionally purging the reaction chamber;
providing, into the reaction chamber, a vapor-phase co-reactant; and
optionally purging the reaction chamber.

In some embodiments, the co-reactant is an oxygen precursor and the material that is deposited may be an oxide of the metal of the coordination compound. The oxygen precursor may provide oxygen for forming the oxide of the metal. The oxygen precursor may be a gas or a material that can become gaseous and that can be represented by a chemical formula that includes oxygen.

In some of these embodiments, the oxygen precursor is selected from a group that consists of water, molecular oxygen, hydrogen peroxide, ozone and reactive oxygen species. In some embodiments, the oxygen precursor comprises hydrogen and oxygen. In some embodiments, the oxygen precursor does not contain carbon, i.e., is carbon-free. In some embodiments, the oxygen precursor does not contain silicon, i.e., is silicon-free. In some embodiments, the oxygen precursor comprises water. In some embodiments, the oxygen precursor is water. In some embodiments, the oxygen precursor is molecular oxygen. In some embodiments, the oxygen precursor comprises hydrogen peroxide. In some embodiments, the oxygen precursor is hydrogen peroxide. In some embodiments, the oxygen precursor is ozone. Depending on the selected oxygen precursor, the oxygen precursor may be liquid or gaseous in the precursor vessel. However, the invention is not limited thereto, and instead, solid precursors may be used.

In some embodiments, the co-reactant is a nitrogen precursor and the material that is deposited may be a nitride of the metal of the coordination compound. The nitrogen precursor may provide nitrogen for forming the nitride of the metal. The term nitrogen precursor can refer to a gas or a material that can become gaseous and that can be represented by a chemical formula that includes nitrogen. In some embodiments, the chemical formula includes nitrogen and hydrogen. In some embodiments, the nitrogen precursor does not include diatomic nitrogen. In embodiments, the nitrogen precursor may be selected from one or more of ammonia (NH₃), hydrazine (N₂H₄), and other compounds comprising or consisting of nitrogen and hydrogen. For example, a mixture of nitrogen gas and hydrogen gas may be used. In embodiments, the nitrogen precursor does not include diatomic nitrogen, i.e., the nitrogen precursor is a non-diatomic precursor.

In some embodiments, the nitrogen precursor is selected from a group consisting of molecular nitrogen (N₂), ammonia (NH₃), hydrazine (NH₂NH₂) and a hydrazine derivative, such as tert-butylhydrazine. In some embodiments, the nitrogen precursor does not contain carbon, i.e., the nitrogen precursor may be carbon-free. In some embodiments, the nitrogen precursor does not contain silicon, i.e., the nitrogen precursor may be silicon-free. Depending on the selected nitrogen precursor, the nitrogen precursor may be liquid or gaseous in the precursor vessel upon vaporization. However, the invention is not limited thereto, and the nitrogen precursor may be solid.

In some embodiments, the nitrogen precursor comprises ammonia. In some embodiments, the nitrogen precursor consists essentially of, or consists of, ammonia. In some embodiments the nitrogen precursor comprises an alkylamine. In some embodiments the nitrogen precursor consists essentially of, or consists of, an alkylamine. Examples of alkylamines include dimethylamine, n-butylamine and tert-butylamine.

In some embodiments, the nitrogen precursor comprises hydrazine. In some embodiments, the nitrogen precursor consists essentially of, or consists of hydrazine. In some embodiments the nitrogen precursor comprises hydrazine substituted by one or more alkyl or aryl substituents. In some embodiments the nitrogen precursor consists essentially of, or consists of, hydrazine substituted by one or more alkyl or aryl substituents. In some embodiments, the hydrazine derivative comprises an alkyl-hydrazine including at least one of: tert-butylhydrazine (C4H₉N₂H₃), methylhydrazine (CH₃NHNH₂), 1,1-dimethylhydrazine ((CH₃)₂NNH₂), 1,2-dimethylhydrazine (CH₃NHNHCH₃), ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, or azo-tert-butane.

In some embodiments, the co-reactant is a reducing agent and the material that is deposited may be the (pure or metallic) metal of the coordination compound. The term “reducing agent” may refer to a gas or a material that can become gaseous and that can reduce the deposited coordination compound into metal. The reducing agent may be provided to the reaction chamber in a gas or vapor phase. The reducing agent may be contacted with the substrate comprising the coordination compound chemisorbed to the substrate. The reduction of the coordination compound to metal may take place at the substrate surface. In some embodiments, the reduction may take place at least partially in the gas phase. The introduction of the coordination compound and the reducing agent into the reaction chamber may at least partially overlap. In some embodiments, the introduction of the coordination compound and the reducing agent into the reaction chamber may be simultaneous. However, in some embodiments, introduction of the coordination compound and the reducing agent into the reaction chamber may be at least partially separate.

In some embodiments, the reducing agent may comprise hydrogen. In some embodiments, the reducing agent may comprise molecular hydrogen (H₂) or plasma derived from H₂.

In some embodiments, the reducing agent may comprise boron. In some embodiments, the reducing agent comprises, consists essentially of, or consists of, diborane (B₂H₆) or neutral ligand adducts of borane (BH₃).

In some embodiments, the reducing agent comprises nitrogen. In some embodiments, the reducing agent may comprise, consist essentially of, or consist of, hydrazine, or a derivative thereof. In some embodiments, the reducing agent may comprise an alkylhydrazine or a dialkylhydrazine. In some embodiments, the reducing agent may comprise a diazenyl compound. The diazenyl compound may be azo-tert-butane. In some embodiments, the reducing agent may comprise, consist essentially of, or consist of 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl)hydrazine, 1-ethyl-1-(p-tolyl)hydrazine, 1-aminoimidazole, 1-amino-2,6-dimethylpiperidine, N-aminoaziridine, or azo-tert-butane.

In some embodiments, the reducing agent may comprise, consist essentially of, or consist of one or more hydrocarbon-substituted hydrazine reducing agents. In some embodiments, the substituted hydrazine may comprise one or more alkyl groups. Each alkyl group may comprise one or more, such as two, three, four, five, six, seven or eight carbon atoms. The number of alkyl groups in a substituted hydrazine reducing agent may be one, two, three or four. For the purposes of the current disclosure, an alkyl group may be an aryl group. Thus, the reducing agent according to the current disclosure may comprise phenyl hydrazine, or diphenyl hydrazine, for example.

In some embodiments, the co-reactant may comprise boron. In these embodiments, the material that is formed on the portion of the surface may be a boride of the metal. In these embodiments, the co-reactant may comprise B₂H₆, adducts of BH₃, or higher order boranes of the formula BₓH_{y}.

In some embodiments, the co-reactant may be a hydrocarbon. In these embodiments, the material that is formed on the portion of the surface may be a carbide of the metal. The hydrocarbon may be aliphatic or aromatic. The hydrocarbon may be saturated or unsaturated, linear or branched, cyclic or acyclic. The hydrocarbon may comprise, for example, an alkyl halide, an alkene, an alkyne, or metal alkyl.

In some embodiments, the process comprises one or more acyclic (i.e., continuous) phases. In some embodiments, the deposition process comprises the continuous flow of the precursor and/or the co-reactant. In such an embodiment, the process may comprise a continuous flow of the precursor.

In some embodiments, at least one of the precursor and the co-reactant is provided into the reaction chamber in pulses. In some embodiments, the precursor is supplied in pulses and the co-reactant is supplied in pulses, and the reaction chamber is purged between consecutive pulses of the precursor and the co-reactant. A duration of providing the precursor and the co-reactant into the reaction chamber (i.e., a pulse time for the precursor, and a pulse time for the co-reactant, respectively) may each independently be, for example, from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The pulse time for the precursor, and the pulse time for the co-reactant may each independently be, for example, 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, the pulse time for the precursor may be at least 5 seconds, or at least 10 seconds. In some embodiments, the pulse time for the precursor may be at most 5 seconds, or at most 10 seconds or at most 20 seconds, or at most 30 seconds. In some embodiments, the pulse time for the co-reactant may be at least 5 seconds, or at least 10 seconds, or at least 20 seconds. In some embodiments, the pulse time for the co-reactant may be at most 5 seconds, or at most 10 seconds or at most 20 seconds, or at most 30 seconds.

In some embodiments, providing the precursor and/or providing the co-reactant into the reaction chamber may comprise pulsing the precursor and/or pulsing the co-reactant into the reaction chamber over the substrate. In some embodiments, the precursor may be pulsed more than one time, for example, two, three, or four times, before the co-reactant is pulsed to the reaction chamber. Similarly, there may be more than one pulse, such as two, three, or four pulses, of the co-reactant before the precursor is pulsed (i.e., provided) into the reaction chamber.

In some embodiments, the method comprises one or more purging steps to remove any precursor and/or co-reactants, and/or vapor phase byproducts from the reaction chamber. Purging may comprise evacuating the reaction chamber with a vacuum pump and/or by replacing the gas inside a reaction chamber with an inert or substantially inert gas such as argon or nitrogen. Purging may limit or prevent interactions between, for example, the precursor and the co-reactant in the vapor phase. Purging may be effected either in time or in space, or both. In embodiments, a purge step may comprise providing a purge gas to the reaction chamber while simultaneously pumping gas from the reaction chamber, wherein the substrate on which the layer is deposited does not move. Said purging step may be performed for from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s, but other purge times can be utilized if necessary. In embodiments, a purge step may comprise: moving the substrate from a first location to which the precursor is continuously supplied, to a second location to which the co-reactant is continuously supplied, through a purge gas curtain or another means of separating the first location from the second location.

The substrate being provided in the reaction chamber typically means that the substrate is in a space where deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of the vapor deposition method can be performed within a single reaction chamber, or they can be performed in multiple reaction chambers, such as reaction chambers of a cluster tool, or deposition stations of a multi-station processing chamber.

The reaction chamber is typically a semiconductor processing apparatus reaction chamber. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be a single wafer atomic layer deposition reactor. In some embodiments, the reaction chamber may be a high-volume manufacturing single wafer atomic layer deposition reactor. In some embodiments, the reaction chamber may be a batch reactor for manufacturing multiple substrates simultaneously.

The reaction chamber may form part of a vapor deposition system. The reaction chamber may form part of a chemical vapor deposition system. In some embodiments, said chemical vapor deposition is atomic layer deposition. The reaction chamber can form part of an atomic layer deposition system. In some embodiments, the system or the reaction chamber may be provided with a heater to activate reactions by elevating the temperature of one or more of the substrate, precursors, and co-reactants.

The substrate may be a semiconductor wafer, such as a silicon wafer, a gallium arsenide wafer, a silicon carbide wafer, a germanium wafer, or an indium phosphide wafer, although the invention is not limited thereto. In embodiments, the portion of the surface of the substrate is reactive towards the coordination compound. In embodiments, the portion of the surface of the substrate may be functionalized for facilitating chemical adsorption (or chemisorption) of the coordination compound. In some embodiments, the portion of the surface may be functionalized with a group selected from a group consisting of: hydroxyl groups, amino groups, carboxyl groups, thiols, silane groups, or combinations thereof. However, this is not essential, and instead, the coordination compound may be deposited without a reaction with the surface.

Any features of any embodiment of the third aspect may be independently as correspondingly described for any embodiment of any of the other aspects of the present invention.

In a fourth aspect, a method of synthesizing a composition comprising a precursor comprising a coordination compound comprising:
a metal from group 4, group 5, group 6 or group 13, and
at least one enaminolate ligand.

The composition comprising the precursor comprising the coordination compound is described in the first aspect of the present disclosure.

The precursor according to the current disclosure is suitable for being used in vapor deposition processes, such as ALD or CVD.

Synthesis Route 1: Alkali Metal Salt of an Enaminolate Ligand Reacted with a Metal Halide

In some embodiments, the synthesis is performed by reacting an alkali metal salt of an enamine with a halide of the desired group 4, group 5, group 6 or group 13 metal.

In some embodiments, the synthesis of a coordination compound comprising a metal from group 4, group 5, group 6 or group 13, and at least one enaminolate ligand is performed by reacting a potassium salt (or another alkali metal salt) of an enamine with a halide of the desired group 4, group 5, group 6 or group 13 metal. In some embodiments, the synthesis is performed by reacting a sodium salt of an enamine with a halide of the desired group 4, group 5, group 6 or group 13 metal.

In some embodiments, the alkali metal salt of an enamine comprises a compound of formula (III)

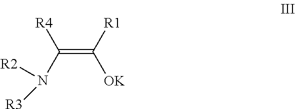

wherein R1 is hydrogen or a C1 to C8 alkyl group, and wherein R2 and R3 are each independently selected from C1 to C8 alkyl groups, or wherein R2, R3 and the N to which they are bonded together form a four to nine membered ring, and wherein R4 is hydrogen or a C1 to C8 alkyl group. The alkali metal salt shown in formula (III) is a potassium salt; however, the alkali metal salt may comprises another alkali metal such as Na or Li.

In some embodiments, the halide of the group 4, group 5, group 6 or group 13 metal is a chloride. In some embodiments, the halide of the group 4, group 5, group 6 or group 13 metal is an iodide. In some embodiments, the halide of the group 4, group 5, group 6 or group 13 metal is a bromide. In some embodiments, the halide of the group 4, group 5, group 6 or group 13 metal is a fluoride.

In embodiments, in which the metal in the coordination compound is titanium, the metal halide is selected from titanium chloride (II) (TiCl₂), titanium chloride (III) (TiCl₃), and titanium chloride (IV) (TiCl₄). In some embodiments, the metal halide is TiCl₄.

In embodiments, in which the metal in the coordination compound is zirconium, the metal halide is selected from zirconium chloride (II) (ZrCl₂), zirconium chloride (III) (ZrCl₃), and zirconium chloride (IV) (ZrCl₄). In some embodiments, the metal halide is ZrCl₄.

In embodiments, in which the metal in the coordination compound is hafnium, the metal halide is selected from hafnium chloride (II) (HfCl₂), hafnium chloride (III) (HfCl₃), and hafnium chloride (IV) (HfCl₄). In some embodiments, the metal halide is HfCl₄.

In embodiments, in which the metal in the coordination compound is vanadium, the metal halide is selected from a group consisting of vanadium(II) chloride (VCl₂), vanadium(III) chloride (VCl₃) and vanadium(IV) chloride (VCl₄). In some embodiments, the metal halide is VCl₄. In some embodiments, the metal halide is VCl₃.

In embodiments, in which the metal in the coordination compound is niobium, the metal halide is selected from a group consisting of niobium(II) chloride (NbCl₃), niobium(IV) chloride (NbCl₄) and niobium(V) chloride (NbCl₅). In some embodiments, the metal halide is NbCl₅.

In embodiments, in which the metal in the coordination compound is tantalum, the metal halide is selected from a group consisting of tantalum(V) chloride (TaCl₅), tantalum(V) bromide (TaBr₅) and tantalum(V) iodide (TaI₅). In some embodiments, the metal halide is TaCl₅.

In embodiments, in which the metal in the coordination compound is chromium, the metal halide is selected from a group consisting of chromium(II) chloride (CrCl₂, chromium(III) chloride (CrCl₃), chromium(II) bromide (CrBr₂), chromium(II) bromide (CrBr₃), chromium(II) iodide (CrI₂) and chromium(II) iodide (CrI₃). In some embodiments, the metal halide is CrCl₃.

In embodiments, in which the metal in the coordination compound is molybdenum, the metal halide is selected from a group consisting of molybdenum(II) chloride (MoCl₃), molybdenum(IV) chloride (MoCl₄), molybdenum(V) chloride (MoCl₅) and molybdenum(VI) chloride (MoCl₆). In some embodiments, the metal halide is MoCl₆. In some embodiments, the metal halide is MoCl₅.

In embodiments, in which the metal in the coordination compound is tungsten, the metal halide is selected from a group consisting of tungsten(IV) chloride (WCl₄), tungsten(V) chloride (WCl₅) and tungsten(VI) chloride (WCl₆). In some embodiments, the metal halide is WCl₅.

In embodiments, in which the metal in the coordination compound is aluminum, the metal halide is selected from a group consisting of aluminum chloride (AlCl₃), aluminum bromide (AlBr₃) and aluminum iodide (AlI₃).

In embodiments, in which the metal in the coordination compound is gallium, the metal halide is selected from a group consisting of gallium chloride (GaCl₃), gallium bromide (GaBr₃) and gallium iodide (GaI₃).

In embodiments, in which the metal in the coordination compound is indium, the metal halide is selected from a group consisting of indium chloride (InCl₃), indium bromide (InBr₃) and indium iodide (InI₃).

Synthesis route 2: Free ligand reacted with a basic metal compound In some embodiments, the synthesis of a coordination compound comprising a metal from group 4, group 5, group 6 or group 13, and at least one enaminolate ligand according to the current disclosure is performed by reacting a free ligand precursor, i.e. protonated form of the ligand with a basic compound of the desired group 4, group 5, group 6 or group 13 metal to form the metal enaminolate coordination complex.
In some embodiments, the free ligand precursor is a compound of formula (IV)

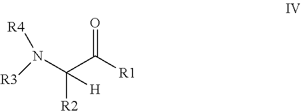

wherein R1 is hydrogen or a C1 to C8 alkyl group, and wherein R2 and R3 are each independently selected from C1 to C8 alkyl groups, or wherein R2, R3 and the N to which they are bonded together form a four to nine membered ring, and wherein R4 is hydrogen or a C1 to C8 alkyl group.

In some embodiments, the basic compound of group 4, group 5, group 6 or group 13 metal is a homoleptic dialkylamido compound. In some embodiments, the basic compound is a homoleptic dialkylamido compound comprising a group 4 metal. In some embodiments, the basic compound is a homoleptic dialkylamido compound comprising a group 5 metal. In some embodiments, the basic compound is a homoleptic dialkylamido compound comprising a group 6 metal. In some embodiments, the basic compound is a homoleptic dialkylamido compound comprising a group 13 metal.

In some embodiments, the homoleptic dialkylamido compound may comprise aluminum and have the formula (V)

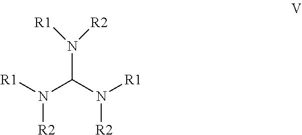

wherein R1 and R2 are selected from C1 to C6 alkyls, such as methyl, ethyl, n-propyl, isopropyl and tert-butyl. Although often depicted in monomeric form, such compounds can be present as dimers, as exemplified by formula (VI)

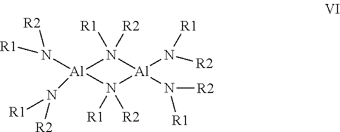

For the purposes of the current disclosure, the description of any particular molecule, both monomeric and dimeric forms are envisaged, whether explicitly mentioned or not.

As a non-limiting example, the homoleptic dialkylamido compound may be selected from tetrakis(ethylmethylamido)zirconium, tetrakis(ethylmethylamido)hafnium, tetrakis(dimethylamido)vanadium, hexakis(dimethylamido)dialuminum, hexakis(dimethylamido)ditungsten, hexakis(dimethylamido)digallium or hexakis(dimethylamido)dimolybdenum.

In some embodiments, the basic compound of group 4, group 5, group 6 or group 13 metal is a homoleptic alkoxide compound. In some embodiments, the basic compound is a homoleptic alkoxide compound comprising a group 4 metal. In some embodiments, the basic compound is a homoleptic alkoxide compound comprising a group 5 metal. In some embodiments, the basic compound is a homoleptic alkoxide compound comprising a group 6 metal. In some embodiments, the basic compound is a homoleptic alkoxide compound comprising a group 13 metal. In some embodiments, the homoleptic alkoxide compound has a formula M(OR)ₓ, wherein M is a group 4, 5, 6 or 13 metal atom, each R is a C1 to C6 alkyl or a phenyl and x is an integer corresponding to the oxidation state of M. In some embodiments, M is a group 4 metal, such as Ti, Zr or Hf. In some embodiments, M is a group 5 metal, such as V, Nb or Ta. In some embodiments, M is a group 6 metal, such as Cr, Mo or W. In some embodiments, M is a group 13 metal, such as Al, Ga or In. In some embodiments, the homoleptic alkoxide compound is triethoxy aluminum (Al(OEt)₃), triethoxy gallium (Ga(OEt)₃), triethoxy indium (ln(OEt)₃), aluminum isopropoxide (Al(iPr)₃). In some embodiments, the homoleptic alkoxide compound is V(OR)₄, where R can be various alkyl groups. Examples of such molecules are V(OMe)₄, V(OEt)₄, and V(OtBu)₄. In some embodiments, the homoleptic alkoxide compound is selected from Nb(OEt)₅, Nb(OMe)₅, Ta(OMe)₅, Ta(OEt)₅, Cr(OtBu)₄, Mo(OEt)₆, Mo(OtBu)₆, W₂(OtBu)₆. In the formulas, Et stands for ethyl, iPr for isopropoxide and tBu for tert-butyl.

In some embodiments, the basic compound is a trialkyl metal compound comprising a group 13 metal. In some embodiments, the trialkyl metal compound comprises three C1 to C6 alkyls. The alkyls may be the same or different. In some embodiments, the trialkyl metal compound is a trimethyl metal compound. In some embodiments, the trialkyl metal compound is a triethyl metal compound. In some embodiments, the trialkyl metal compound is a tris-propyl metal compound. In some embodiments, the basic compound is a trialkyl aluminum compound. In some embodiments the basic compound is a trialkyl indium compound. In some embodiments the basic compound is a trialkyl gallium compound. In some embodiments, the trialkyl metal compound is trimethylaluminum. In some embodiments, the trialkyl metal compound is trimethylindium. In some embodiments, the trialkyl metal compound is trimethylgallium. In some embodiments, the trialkyl metal compound is triethylaluminum. In some embodiments, the trialkyl metal compound is triethylindium. In some embodiments, the trialkyl metal compound is triethylgallium.

The synthesis of a coordination compound according to the current disclosure may be performed in liquid phase, using conventional solvents, such as tetrahydrofuran or toluene, as a solvent. The synthesis may be performed at a temperature between 0° C. and 150° C., for example at a temperature of between 15° C. and 115° C., such as at a temperature of between 20° C. and 66° C. The duration of reacting the components of the synthesis reaction is selected by the reactivity of the specific molecules, temperature and other factors known in the art to influence the speed of reactions in the art of chemical synthesis.

In some embodiments, the obtained coordination compound is purified. The purification may be performed to obtain purity conforming to the requirements of semiconductor industry. In some embodiments, the coordination compound according to the current disclosure is a liquid at room temperature. In some embodiments, the coordination compound according to the current disclosure is a solid at room temperature. The selected purification method may depend on the phase of the coordination complex. In embodiments in which the coordination complex is liquid, it may be purified by distillation. In embodiments, in which the coordination complex according to the current disclosure is a solid, it can be purified by recrystallization. In embodiments in which the coordination complex according to the current disclosure is a solid, it can be purified by sublimation.

Any features of any embodiment of the fourth aspect may be independently as correspondingly described for any embodiment of any of the other aspects of the present invention.

In a fifth aspect, the present invention relates to a system, e.g., a semiconductor processing apparatus, for depositing a material comprising a metal from group 4, group 5, group 6 or group 13 on a substrate. The system comprises a reaction chamber for receiving, or comprising, the substrate. The system further comprises a first source for providing a vapor-phase composition comprising a precursor comprising a coordination compound, wherein the first source is in gas communication via a first valve with the reaction chamber. The coordination compound comprises the metal, and at least one enaminolate ligand.

The composition comprising the precursor comprising the coordination compound is described in the first aspect of the present disclosure.

The system further comprises a controller operably connected to the first valve, wherein the controller is configured and programmed to open the first valve to provide a flow of the composition into the reaction chamber and to close the first valve to cease the flow of the composition into the reaction chamber. The first source may comprise the precursor vessel in accordance with embodiments of the second aspect of the present invention.

In embodiments, the system further comprises a second source, in gas communication via a second valve with the reaction chamber. The second source may comprise a co-reactant vessel. The second source may comprise any source suitable for providing the co-reactant, such as a compressed gas cylinder, in which the co-reactant may be contained as a pressurized gas, or a co-reactant generator, such as an ozone generator. The second source may be for providing a vapor-phase co-reactant. In these embodiments, the system may further comprise a controller operably connected to the second valve, wherein the controller is configured and programmed to open the second valve to provide a flow of the co-reactant into the reaction chamber and to close the second valve to cease the flow of the co-reactant into the reaction chamber. The controller operably connected to the first valve may be the same as the controller operably connected to the second valve, but the invention is not limited thereto.

In embodiments, the system is a semiconductor processing apparatus. In embodiments, the reaction chamber comprises the substrate. The first source may comprise the precursor vessel in accordance with embodiments of the second aspect of the present invention.

The precursor vessel may have an inlet fluidically coupled to a source of a carrier gas. The carrier gas may be an inert gas such as N₂, He or Ar. The carrier gas may sweep a vapor of the precursor, along with it through the precursor vessel outlet into the reaction chamber.

The system may comprise heaters, that may be operated by a controller, for keeping the vapor-phase composition at or above the volatilization temperature of the precursor so as to prevent undesirable condensation in the valves, filters, conduits, and other components associated with delivering the vapor-phase composition into the reaction chamber. In addition to a heater for heating the precursor vessel, as described elsewhere in the present description, additional heaters may be provided for heating the various valves and gas flow lines between the precursor vessel and the reaction chamber, to prevent the vapor-phase composition from condensing and depositing on such components. Gas-conveying components between the precursor vessel and the reaction chamber may be provided in which the temperature is maintained above the volatilization temperature of the precursor (i.e., “hot zone”).

In embodiments, the system further comprises a device for purging the reaction chamber, such as a device for performing inert gas purging on the reaction chamber or a device for vacuum pumping the reaction chamber. The system may further comprise a controller for activating said purging device to purge the reaction chamber. The controller may be configured and programmed to purge the reaction chamber after closing of the first valve and before opening of the second valve, and/or after closing of the second valve and before opening of the first valve.

Any features of any embodiment of the fifth aspect may be independently as correspondingly described for any embodiment of any of the other aspects of the present invention.

### Example: Deposition of a Material Comprising a Transition or Lanthanide Metal

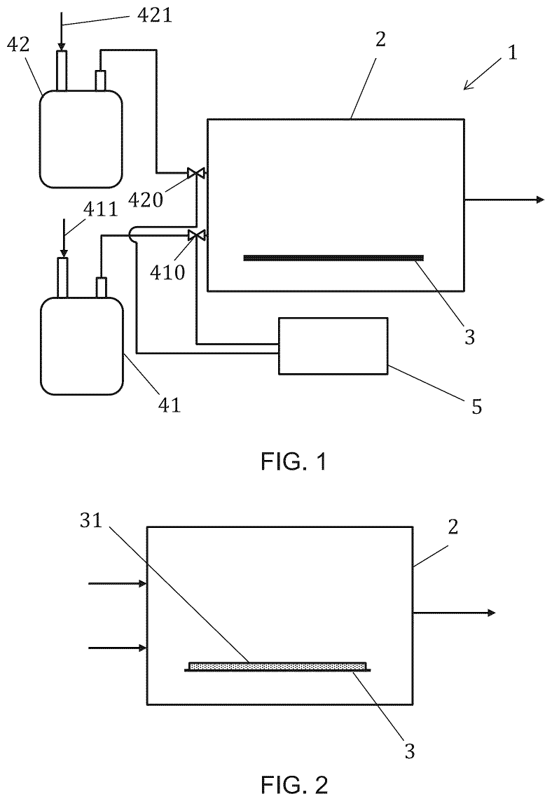

A schematic representation of a deposition system (1) in accordance with embodiments of the present invention is shown in FIG. 1.

The deposition system (1) comprises a reaction chamber (2) for receiving the substrate (3) on which a thin film is to be formed.

The deposition system (1) further comprises a first source (41) comprising a precursor vessel in accordance with embodiments of the present invention, connected, at an outlet of the vessel, via a first valve (410) to the reaction chamber (2) for providing a vapor-phase precursor and a controller (5) operably connected to the first valve (410). The controller (5) is configured and programmed to open and close the first valve (410) to control the flow of the vapor-phase precursor into the reaction chamber (2). The vapor-phase precursor comprises a coordination compound comprising a metal from group 4, group 5, group 6 or group 13, and at least one enaminolate ligand.

The deposition system (1) further comprises a second source (42) connected, at an outlet of the second source (42), via a second valve (420) to the reaction chamber (2) for providing a co-reactant. Although the second source (42) is in FIG. 1 depicted as a vessel, the second source (42) may comprise any source suitable for providing the co-reactant. In embodiments, the co-reactant may, for example, be NH₃ or O₂, and the second source may comprise a compressed gas cylinder containing said co-reactant as a compressed gas. In embodiments, the co-reactant may be ozone, and the second source may be an ozone generator adapted for generating ozone from O₂, that may then be delivered to the reaction chamber in the gas phase. The co-reactant may comprise an oxygen source, a nitrogen source, a reducing agent, or any other type of co-reactant, the invention not being limited to any type of co-reactant. The deposition system (1) further comprises a controller (5) operably connected to the second valve (420). The controller (5) is configured and programmed to open and close the second valve (420) to control the flow of the co-reactant into the reaction chamber (2).

Now, a cycle of deposition steps is described in accordance with embodiments of the present invention. The first valve (410) is opened by the controller (5). An inert carrier gas (411) is provided, via an inlet of the precursor vessel (41), into the precursor vessel (41), for inducing a flow of the precursor, through the outlet of the precursor vessel (41), through the first valve (410), into the reaction chamber (2). Instead of using the inert carrier gas, or in addition thereto, a flow of the precursor from the precursor vessel (41) into the reaction chamber (2) may be induced by providing a pressure difference between the precursor vessel (41) and the reaction chamber (2).

Thereby, as schematically shown in FIG. 2, a thin film is formed on the substrate (3) comprising the deposited coordination compound, which may be a chemisorbed coordination compound. The chemisorbed coordination compound may contain part of the vapor-phase coordination compound, although another part of the vapor-phase coordination compound may have reacted away in the reaction for chemisorbing the coordination compound. In the present example, the metal M of the chemisorbed coordination compound may be bonded to the surface of the substrate (3). In embodiments of the present invention, the chemisorbed coordination compound may comprise the metal from the coordination compound, which may be bonded to one or more enaminolate ligands and/or one or more optional other ligands from the coordination compound.

Next, the first valve (410) may be closed by the controller (5). The reaction chamber (2) may be purged from non-deposited, vapor-phase precursor.

Subsequently, the second valve (420) may be opened by the controller (5), and the vapor-phase co-reactant may be introduced into the reaction chamber (2), over the substrate surface (3). For this, an inert carrier gas (421) may be introduced, through an inlet of the second source (42), into the second source (42), to provide a flow of the carrier gas together with the co-reactant, via an outlet of the second source (42), through the second valve (420), into the reaction chamber (2). The co-reactant may react with the deposited coordination compound. For example, water may be provided as co-reactant, which may react with any enaminolate ligand of the chemisorbed coordination compound so as to remove the enaminolate ligand from the chemisorbed coordination compound.

Next, the second valve (420) may be closed by the controller (5). The reaction chamber (2) may be purged from non-reacted, vapor-phase co-reactant.

The above steps may be cyclically performed, so as to form a thin film (31) of deposited material, of which the chemical composition depends on the type of co-reactant, and typically comprises at least the metal of the coordination compound.

Although in the present example a cyclic chemical vapor deposition process comprising cyclically providing the coordination compound of embodiments of the present invention, and a co-reactant, into the reaction chamber, the invention is not limited thereto. Any type of vapor deposition process may be performed in accordance with embodiments of the present invention, including non-cyclic processes and non-chemical processes.

It is to be understood that although preferred embodiments, specific constructions and configurations, as well as materials, have been discussed herein for devices according to the present invention, various changes or modifications in form and detail may be made without departing from the scope of this invention. Steps may be added or deleted to methods described within the scope of the present invention.

1. A composition comprising a coordination compound comprising:
a metal from group 5, group 6 or group 13, and
at least one enaminolate ligand.

2. The composition of claim 1, wherein the metal is from group 5 or group 6.

3. The composition of claim 2, wherein the metal is selected from a group consisting of vanadium, niobium, and tantalum.

4. The composition of claim 2, wherein the metal is selected from a group consisting of chromium, molybdenum, and tungsten.

5. The composition of claim 1, wherein each enaminolate ligand has the following chemical formula: 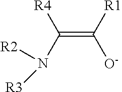
wherein R1 is hydrogen or a C1 to C8 alkyl group or an alkylsilyl group,
wherein R2 and R3 are each independently selected from C1 to C8 alkyl groups or alkylsilyl groups, or
wherein R2, R3 and the N to which they are bonded together form a four to nine membered ring, and
wherein R4 is hydrogen or a C1 to C8 alkyl group or an alkylsilyl group.

6. The composition of claim 5, wherein R1 is hydrogen or a C1 to C6 alkyl group, and wherein R2 and R3 are each independently selected from C1 to C6 alkyl groups.

7. The composition of claim 6, wherein R1 is selected from a group consisting of hydrogen, methyl, ethyl, n-propyl, isopropyl, n-butyl, sec-butyl, and tert-butyl, and
wherein R2 and R3 are each independently selected from a group consisting of methyl, ethyl, and isopropyl.

8. The composition of claim 1, wherein the metal is in an oxidation state below the highest common oxidation state for the metal.

9. The composition of claim 1, wherein the coordination compound is homoleptic.

10. The composition of claim 9, wherein the coordination compound has the chemical formula ML₃, wherein M is selected from a group consisting of V, Nb, Ta, Cr, Mo, W, Al, Ga and In, and wherein each L is an enaminolate ligand.

11. The composition of claim 1, wherein the coordination compound is heteroleptic.

12. The composition of claim 11, wherein the coordination compound further comprises at least one ligand selected from a group consisting of: a cyclopentadienyl ligand, an amidinate ligand, an amidate ligand, an alkyl ligand, an alkylamido ligand, an imido ligand, an alkoxide ligand, a halide ligand, a guanidinate ligand, and a beta-diketonate ligand.

13. The composition of claim 11, wherein the coordination compound has the chemical formula MO₂L₂, wherein M is Cr, Mo, or W, and wherein each L is an enaminolate ligand.

14. The composition of claim 11, wherein the coordination compound has the chemical formula MOL₃, wherein M is V, Nb, or Ta, and wherein each L is an enaminolate ligand.

15. The composition of claim 11, wherein the coordination compound has the chemical formula M(NR)ₓL_{y}, wherein M is V, Nb, Ta, Cr, Mo, or W,
wherein each R is an alkyl group or a trialkylsilyl group,
wherein each L is an enaminolate ligand, and
wherein each of x and y is an integer equal to or greater than one, and wherein x+y is an integer from two to six.

16. The composition of claim 11, wherein the coordination compound has the chemical formula MLₓL′_{y}, wherein M is V, Nb, Ta, Cr, Mo, or W,
wherein each L is an enaminolate ligand, and wherein each L′ is a ligand selected from a group consisting of: dimethylamido, diethylamido, ethylmethylamido, methoxy, ethoxy, isopropoxy, tert-butoxy, tert-pentoxy, trimethylsiloxy, or triethylsiloxy, N,N′-diisopropylacetamidinate, N,N′-di-tert-butylacetamidinate, N,N′-diisopropylformamidinate, N,N′-di-tert-butylformamidinate, cyclopentadienyl, methylcyclopentadienyl, ethylcyclopentadienyl, isopropylcyclopentadienyl, tert-butylcyclopentadienyl, trimethylsilylcyclopentadienyl, and pentamethylcyclopentadienyl, and
wherein each of x and y is an integer equal to or greater than one, and wherein x+y is an integer from two to six.

17. A precursor vessel comprising the composition of claim 1,
wherein the precursor vessel is configured to supply a vapor of the coordination compound to a reaction chamber of a vapor deposition system.

18. A method for depositing a material comprising a metal from group 4, group 5, group 6 or group 13 on a substrate, the method comprising:
providing a substrate in a reaction chamber, and then
providing, into the reaction chamber, a vapor-phase composition comprising a precursor comprising a coordination compound comprising:
the metal, and
at least one enaminolate ligand,
thereby forming a layer comprising the metal on a portion of a surface of the substrate.

19. The method of claim 18, further comprising executing at least one cycle of a cyclic deposition process, each cycle comprising:
providing, into the reaction chamber, the vapor-phase composition;
optionally purging the reaction chamber;
providing, into the reaction chamber, a vapor-phase co-reactant; and
optionally purging the reaction chamber.

20. A system for depositing a material comprising a metal from group 4, group 5, group 6 or group 13 on a substrate, the system comprising:
a reaction chamber for receiving the substrate,
a first source for providing a vapor-phase composition comprising a precursor comprising a coordination compound, wherein the first source is in gas communication via a first valve with the reaction chamber, the coordination compound comprising:
the metal, and
at least one enaminolate ligand,
a controller operably connected to the first valve, wherein the controller is configured and programmed to open the first valve to provide a flow of the composition into the reaction chamber and to close the first valve to cease the flow of the composition into the reaction chamber.
